(19) United States
(12) Patent Application Publication
(10) Pub. No.: US 2025/0326038 A1
(43) Pub. Date: Oct. 23, 2025

(54) COATED CUTTING TOOL

(71) Applicant: AB SANDVIK COROMANT, Sandviken (SE)

(72) Inventors: Ebba SAIKOFF, Sandviken (SE); Lars JOHNSON, Sandviken (SE)

(21) Appl. No.: 18/869,881

(22) PCT Filed: May 31, 2023
(86) PCT No.: PCT/EP2023/064546

§ 371 Date: Nov. 27, 2024

(30) Foreign Application Priority Data
Jun. 1, 2022 (EP) 22176755.1

(51) Int. Cl. B23B 27/14; C23C 14/06; C23C 14/32

(52) U.S. Cl. CPC B23B 27/148; C23C 14/0641; C23C 14/325; B23B 2228/105

(57) ABSTRACT

The present invention relates to a coated cutting tool including a substrate and a coating. The coating includes a nano-multilayer of alternating layers of a first nanolayer being Ti₁₋ₓAlₓN, 0.55<x≤0.70, and a second nanolayer being Ti_{1-y-z}Al_{y}Si_{z}N, 0.20≤y≤0.50, 0.13≤z≤0.25, 0.46≤y+z≤0.65. A sequence of one first nanolayer and one second nanolayer forms a layer period, wherein the average layer period thickness in the nano-multilayer is ≤20 nm.

The present invention relates to a coated cutting tool comprising a nano-multilayer of (Ti,Al)N and (Ti,Al,Si)N.

### INTRODUCTION

Commonly, a cutting tool for metal machining comprises a hard substrate material such as cemented carbide which has a thin hard wear resistant coating. A cutting tool generally has at least one rake face and at least one flank face. A cutting edge is present where a rake face and flank face meet.

Nano-multilayered coatings are commonly used in the area of cutting tools for metal machining. In these coatings at least two sublayers which are different in some respect alternate forming a coating of a stack of nanolayers. Various metal nitrides are commonly used in wear resistant coatings of cutting tools.

Metal machining operations include, for example, turning, milling, and drilling.

In order to provide a long tool life a coated cutting tool, such as an insert, should have high resistance against different types of wear, e.g., flank wear resistance, crater wear resistance, chipping resistance and flaking resistance.

Different metal machining operations affect a coated cutting tool in different ways. Turning, for example, is a continuous metal machining operation while milling is more intermittent in nature. In milling the thermal and mechanical load will vary over time. Thermal tensions are induced which may lead to so-called thermal cracks, herein referred to as “comb cracks”, in the coatings, while the later may cause fatigue in the cutting edge leading to chipping, i.e., small fragments of the cutting edge loosening from the rest of the substrate. Thus, common wear types of a coated cutting tool in milling are cracking and chipping. Increasing the comb crack resistance is thus of great importance to increase tool lifetime.

A high level of toughness of the coating, in particular at the cutting edge, i.e., high edge line toughness, is also beneficial for reducing chipping.

Flank wear obviously takes place on a flank face of the cutting edge, mainly from an abrasive wear mechanism. The flank face is subjected to workpiece movement and too much flank wear will lead to poor surface texture of the workpiece, inaccuracy in the cutting process and increased friction in the cutting process. If a better flank wear resistance is provided longer tool life is provided for certain metal machining operations.

A coating must also remain adherent to the substrate, i.e., not flake off, during a machining operation. Some workpiece material types such as ISO-M (stainless steel) and ISO-S (heat resistant super alloys and, e.g., titanium), are so called sticky materials and induce flaking more than other workpiece material types. These material types also have a smearing behaviour which means that workpiece material is smeared onto the cutting tool surface which eventually may lead to the formation of a built-up edge (BUE) of workpiece material on the cutting edge. Such a BUE may cause the coating to flake off or even rip off a part of the edge of the cutting tool.

There is a continuing demand for coated cutting tools in which the coating has excellent properties in terms of flank wear resistance, comb crack resistance, flaking resistance, edge line toughness etc. in order to provide a cutting tool with superior properties than currently available cutting tools on the market. If one or more of the above-mentioned properties are improved then longer tool life is provided.

There is an object of the present invention to provide a coated cutting tool which, at least, shows high flank wear resistance during turning operations and high resistance against comb cracks during milling operations.

Furthermore, there is an additional object of the present invention to provide a coated cutting tool which has high flaking resistance during machining of smearing materials, such as stainless steel.

### Definitions

By the term “average layer period thickness” is meant the average thickness of a combination A-B in the nano-multilayer coating of a first nanolayer A and second nanolayer B in a nano-multilayer A-B-A-B-A . . . If the deposition process is known the calculation can be made by dividing the total thickness of the nano-multilayer by the number of A-B depositions (which corresponds to the number of revolutions when depositing a substrate in a rotating manner).

Alternatively the calculation being made by using TEM analysis of a cross-section of the nano-multilayer counting the number of consecutive A-B nanolayer combinations over a length of at least 200 nm and calculating an average value.

If the nano-multilayer has a total thickness of only 0.5 μm then the measuring places are located just below the outer surface of the nano-multilayer. Suitably methods of analysis include transmission electron microscopy (TEM).

By the term “FWHM” is meant “Full Width at Half Maximum”, which is the width, in degrees (2theta), of an X-ray diffraction peak at half its peak intensity (for a certain (hkl) diffraction peak).

### The Invention

It has now been provided a nano-multilayered coating of alternating (Ti,Si)N and (Ti,Al,Si)N layers having a surprisingly high comb crack resistance and flank wear resistance.

The present invention relates to a coated cutting tool comprising a substrate and a coating, wherein the coating comprises a nano-multilayer of alternating layers of a first nanolayer being Ti₁₋ₓAlₓN, 0.55<x≤0.70, and a second nanolayer being Ti_{1-y-z}Al_{y}Si_{z}N, 0.20≤y≤0.50, 0.13≤z≤0.25, 0.46≤y+z≤0.65, a sequence of one first nanolayer and one second nanolayer forms a layer period, the average layer period thickness in the nano-multilayer is ≤20 nm.

For the first nanolayer Ti₁₋ₓAlₓN, suitably 0.56≤x≤0.65, preferably 0.58≤x≤0.63, most preferably 0.58≤x≤0.61.

For the second nanolayer Ti_{1-y-z}Al_{y}Si_{z}N, suitably 0.25≤y≤0.45 and 0.13≤z≤0.20, preferably 0.28≤y≤0.40 and 0.14≤z≤0.18, most preferably 0.33≤y≤0.40 and 0.14≤z≤0.17.

For the second nanolayer Ti_{1-y-z}Al_{y}Si_{z}N, suitably 0.46≤y+z≤0.60, preferably 0.47≤y+z≤0.55.

The average layer period thickness of the nano-multilayer is suitably from 2 to 15 nm, for example from 3 to 10 nm, or from 3 to 7 nm.

In one embodiment the nano-multilayer has a columnar microstructure. This means that there are crystallites, or “grains”, of columnar shape in the nano-multilayer which are generally elongated in their growth direction.

In one embodiment, the nano-multilayer has a 200 crystallographic preferred orientation. In this embodiment the intensity ratio I(200)/I(111) in a theta-2theta X-ray diffraction analysis is suitably >5, for example >10, or >20.

In one embodiment, the nano-multilayer has a FWHM value for the cubic (200) peak in X-ray diffraction being from 0.4 to 1 degrees (2theta), for example from 0.5 to 0.9 degrees (2theta), or from 0.6 to 0.8 degrees (2theta).

The (200) peak in XRD used for determining the FWHM value is Cu—K_{α2} stripped.

The thickness of the nano-multilayer is suitably from about 0.5 to about 15 μm, preferably from about 1 to about 10 μm, more preferably from about 1 to about 7 μm, most preferably from about 1.5 to about 4 μm.

The nano-multilayer is suitably a cathodic arc evaporation deposited layer.

In one embodiment the coating comprises a layer of TiN, (Ti,Al)N or (Cr,Al)N below the nano-multilayer, suitably closest to the substrate.

Preferably, the innermost layer is (Ti,Al)N. If (Ti,Al)N is used then the (Ti,Al)N is suitably Ti₁₋ᵥAlᵥN, 0.35≤v≤0.70, preferably 0.45≤v≤0.65, most preferably 0.55<v≤0.65. In a preferred embodiment the Ti—Al relation in the (Ti,Al)N is the same as the Ti—Al relation in the first nanolayer of the nano-multilayer, i.e., in the Ti₁₋ᵥAlᵥN, suitably 0.55≤v≤0.70, for example 0.56≤v≤0.65, or 0.58<v≤0.63, or 0.58<v≤0.61. The thickness of this innermost layer can be from about 0.1 to about 3 μm, from about 0.2 to about 2 μm, most preferably from about 0.5 to about 1.5 μm.

In a preferred embodiment, the coating comprises a nano-multilayer of alternating layers of a first nanolayer being Ti₁₋ₓAlₓN, 0.55<x≤0.65, and a second nanolayer being Ti_{1-y-z}Al_{y}Si_{z}N, 0.25≤y≤0.45 and 0.13≤z≤0.20, 0.46≤y+z≤0.65, the average layer period thickness of the nano-multilayer is from 3 to 10 nm, the thickness of the nano-multilayer is from about 1 to about 7 μm, there is an innermost layer of (Ti,Al)N below the nano-multilayer closest to the substrate having a thickness of from about 0.5 to about 1.5 μm.

In a more preferred embodiment, the coating comprises a nano-multilayer of alternating layers of a first nanolayer being Ti₁₋ₓAlₓN, 0.55<x≤0.63, and a second nanolayer being Ti_{1-y-z}Al_{y}Si_{z}N, 0.28≤y≤0.40 and 0.13≤z≤0.17, 0.47≤y+z≤0.55, the average layer period thickness of the nano-multilayer is from 3 to 10 nm, the thickness of the nano-multilayer is from about 1 to about 7 μm, there is an innermost layer of (Ti,Al)N below the nano-multilayer closest to the substrate having a thickness of from about 0.5 to about 1.5 μm.

The substrate of the coated cutting tool can be selected from the group of cemented carbide, cermet, ceramic, cubic boron nitride and high speed steel. In one embodiment the substrate is a cemented carbide comprising from 5 to 18 wt % Co and from 0 to 10 wt % carbides nitrides or carbonitrides of group 4 to 5 in the periodic table of elements.

Further components like Cr are possible in a cemented carbide substrate, The coated cutting tool is suitably a cutting tool insert, a drill, or a solid end-mill, for metal machining. The cutting tool insert is, for example, a turning insert or a milling insert.

### BRIEF DESCRIPTIONS OF THE DRAWINGS

FIG. 1 shows a schematic view of one embodiment of a cutting tool being a milling insert.

FIG. 2 shows a schematic view of one embodiment of a cutting tool being a turning insert.

FIG. 3 shows a schematic view of a cross section of an embodiment of the coated cutting tool of the present invention showing a substrate and a coating comprising different layers.

### DETAILED DESCRIPTION OF EMBODIMENTS IN DRAWINGS

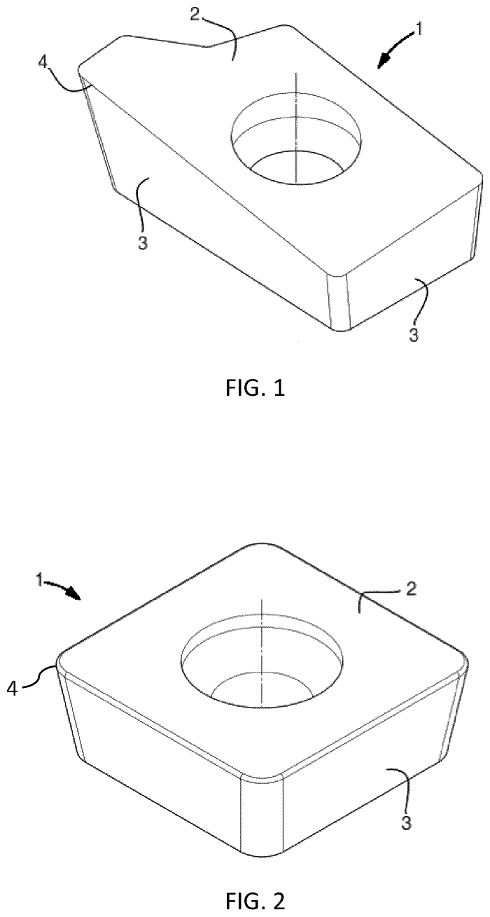

FIG. 1 shows a schematic view of one embodiment of a cutting tool (1) having a rake face (2) and flank faces (3) and a cutting edge (4). The cutting tool (1) is in this embodiment a milling insert. FIG. 2 shows a schematic view of one embodiment of a cutting tool (1) having a rake face (2) and flank faces (3) and a cutting edge (4). The cutting tool (1) is in this embodiment a turning insert.

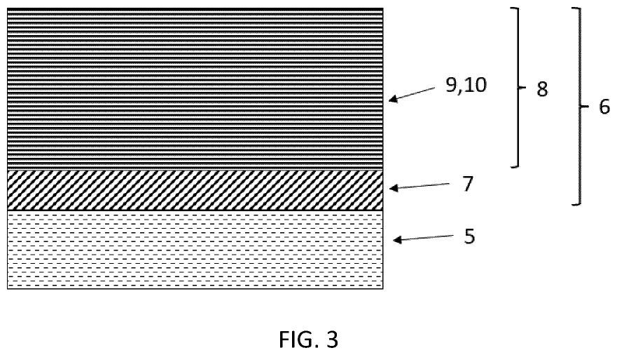

FIG. 3 shows a schematic view of a cross section of an embodiment of the coated cutting tool of the present invention having a substrate body (5) and a coating (6). The coating consisting of a first (Ti,Al)N innermost layer (7) followed by a nano-multilayer (8) of alternating nanolayers being Ti₁₋ₓAlₓN (9) and nanolayers being Ti_{1-y-z}Al_{y}Si_{z}N (10).

### EXAMPLES

### Example 1

Different nano-multilayers of (Ti,Al)N and (Ti,Al,Si)N were deposited on sintered cemented carbide cutting tool insert blanks of the geometries SNMA120408, CNMG120408MM and R390-11. The composition of the cemented carbide was 10 wt % Co, 0.4 wt % Cr and rest WC. The cemented carbide blanks were coated by cathodic arc evaporation in a vacuum chamber comprising four arc flanges. Targets of Ti—Al—Si were mounted in two of the flanges opposite each other. Targets of Ti—Al were mounted in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on pins that undergo a three-fold rotation in the PVD chamber.

### Samples 1-4:

The chamber was pumped down to high vacuum (less than 10⁻² Pa) and heated to 450-550° C. by heaters located inside the chamber. The blanks were then etched for 60 minutes in an Ar plasma.

At first, an innermost, about 1 μm thick, layer of Ti_{0.40}Al_{0.60}N was deposited by using only the Ti—Al targets, which were Ti_{0.40}Al_{0.60} targets. The process conditions when depositing the innermost (Ti,Al)N layer were: a chamber pressure (reaction pressure) of 4 Pa of N₂ gas, and a DC bias voltage of −70 V (relative to the chamber walls) applied to the blank assembly. The cathodes were run in an arc discharge mode at a current of 150 A (each).

Then, both the Ti—Al targets and the Ti—Al—Si targets were employed. The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 75 minutes (4 flanges). A nano-multilayer coating having a thickness of about 3 μm was deposited on the blanks.

Depositions were made with combinations of Ti—Al—Si targets being Ti_{0.50}Al_{0.35}Si_{0.15}, Ti_{0.50}Al_{0.30}Si_{0.20}, Ti_{0.35}Al_{0.55}Si_{0.10} and Ti_{0.30}Al_{0.60}Si_{0.10}, and Ti—Al targets being Ti_{0.40}Al_{0.60}. The total thickness of the deposited nano-multilayers were about 3 μm (as measured on the flank face). The rotational speed correlates to a certain period thickness. In the specific equipment used the rotational speed 5 rpm used correlates to a nanolayer period thickness of about 5 nm.

The samples made are called “Sample 1 (invention)”, “Sample 2 (invention)”, “Sample 3 (comparative)” and “Sample 4 (comparative)”.

### Sample 5:

As a further comparison a coating comprising a nano-multilayer of (Ti,Al)N and (Ti,Si)N was deposited on sintered cemented carbide cutting tool insert blanks of the geometries SNMA120408, CNMG120408MM and R390-11. The composition of the cemented carbide was the same as for samples 1-4. The cemented carbide blanks were coated by cathodic arc evaporation in a vacuum chamber comprising four arc flanges. Targets of Ti—Si were mounted in two of the flanges opposite each other. Targets of Ti—Al were mounted in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on pins that undergo a three-fold rotation in the PVD chamber.

The chamber was pumped down to high vacuum (less than 10⁻² Pa) and heated to 450-550° C. by heaters located inside the chamber. The blanks were then etched for 60 minutes in an Ar plasma.

At first, an innermost, about 1 μm thick, layer of Ti_{0.40}Al_{0.60}N was deposited by using only the Ti—Al targets, which were Ti_{0.40}Al_{0.60} targets. The process conditions when depositing the innermost (Ti,Al)N layer were: a chamber pressure (reaction pressure) of 4 Pa of N₂ gas, and a DC bias voltage of −70 V (relative to the chamber walls) applied to the blank assembly. The cathodes were run in an arc discharge mode at a current of 150 A (each).

Then, both the Ti—Al targets and the Ti—Si targets were employed. The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 75 minutes (4 flanges). A nano-multilayer coating having a thickness of about 3 μm was deposited on the blanks.

The rotational speed correlates to a certain period thickness. In the specific equipment used the rotational speed 5 rpm used correlates to a nanolayer period thickness of about 5 nm.

The samples made are called “Sample 5 (comparative)”.

The samples 1-5 made are listed in Table 1.

TABLE 1

| | Nano-multilayer | | |
|---|---|---|---|
| | First | Second | Al + Si in second |
| Sample | nanolayer | nanolayer | nanolayer |
| 1 | Ti_{0.40}Al_{0.60}N | Ti_{0.50}Al_{0.35}Si_{0.15}N | 0.50 |
| (invention) | | | |
| 2 | Ti_{0.40}Al_{0.60}N | Ti_{0.50}Al_{0.30}Si_{0.20}N | 0.50 |
| (invention) | | | |
| 3 | Ti_{0.40}Al_{0.60}N | Ti_{0.35}Al_{0.55}Si_{0.10}N | 0.65 |
| (comparative) | | | |
| 4 | Ti_{0.40}Al_{0.60}N | Ti_{0.30}Al_{0.60}Si_{0.10}N | 0.70 |
| (comparative) | | | |
| 5 | Ti_{0.40}Al_{0.60}N | Ti_{0.80}Si_{0.20}N | NA |
| (comparative) | | | |

Results from measurements of the actual elemental composition, using energy-dispersive X-ray spectroscopy (EDS), in (Ti,Al)N and (Ti,Al,Si)N coatings have shown that deviations of only 1-2 percentage units from a theoretical composition based on target composition are seen. These small deviations are within the accuracy of the EDS method. It is therefore concluded that the actual elemental composition of Ti, Al and Si in the layers deposited herein substantially correspond well to the respective target compositions used.

### Example 2 (Analysis)

SEM imaging of the samples 1-5 showed that the nano-multilayers had a columnar structure.

Furthermore, X-ray diffraction (XRD) analysis was conducted on the flank face of coated inserts using a PANalytical CubiX3 diffractometer equipped with a PIXcel detector. The coated cutting tool inserts were mounted in sample holders that ensure that the flank face of the samples were parallel to the reference surface of the sample holder and also that the flank face was at appropriate height. Cu-K_{α} radiation was used for the measurements, with a voltage of 45 kV and a current of 40 mA. Anti-scatter slit of ½ degree and divergence slit of ¼ degree were used. The diffracted intensity from the coated cutting tool was measured around 26 angles where relevant peaks occur.

Data analysis, including background subtraction and Cu—K_{α2} stripping, was performed using PANalytical's X'Pert HighScore Plus software. A Pseudo-Voigt-Fit function was used for peak analysis. No thin film correction was applied to the obtained peak intensities. Possible peak overlap of a (111) or (200) peak with any diffraction peak not belonging to the PVD layer, e.g., a substrate reflection like WC, was compensated for by the software (deconvolution of combined peaks) when determining the peak intensities and peak widths. The XRD of the nano-multilayers of the invention shows a 200 crystallographic preferred orientation. There is no significant (111) peak present at all so the intensity ratio I(200)/I(111) is much higher than 20. The full width at half maximum (FWHM) value for the (200) peak of the samples was calculated. The results are shown in Table 2.

TABLE 2

| | Nano-multilayer | | |
|---|---|---|---|
| | First | Second | FWHM I(200), |
| Sample | nanolayer | nanolayer | [°2θ] |
| 1 | Ti_{0.40}Al_{0.60}N | Ti_{0.50}Al_{0.35}Si_{0.15}N | 0.66 |
| (invention) | | | |
| 2 | Ti_{0.40}Al_{0.60}N | Ti_{0.50}Al_{0.30}Si_{0.20}N | 0.64 |
| (invention) | | | |

An FWHM value reflects both the grain size of crystallites in the coating and the point defect density in that the smaller the grain size and/or the greater the point defect density the larger the FWHM value. In this case, the coatings of the invention show a quite small value of FWHM.

### Example 3

Cutting tests were made in order to determine the performance of the samples made.

### Explanations to Terms Used:

The following expressions/terms are commonly used in metal cutting, but nevertheless explained in the table below:
Vc (m/min): cutting speed in meters per minute
fz (mm/tooth): feed rate in millimeter per tooth (in milling)
fn (mm/rev) feed rate per revolution (in turning)
z: (number) number of teeth in the cutter
aₑ (mm): radial depth of cut in millimeter
aₚ (mm): axial depth of cut in millimeter

### Comb Crack Resistance:

Operation: Shoulder milling
Tool holder: R245-080027-12M, Dc=80 mm
Work piece material: Toolox 33 (tool steel), L=600 mm, 1=200 mm, h=100 mm,
Insert type: R390-11
Cutting speed V_{c}=320 m/min
Feed rate f_{z}=0.3 mm/rev
z=1
Depth of cut aₚ=2 mm
Radial engagement aₑ=15 mm
with cutting fluid

The criteria for end of tool life is a max. chipped height VB>0.3 mm.

### Flank Wear Test:

Longitudinal turning
Work piece material: Sverker 21 (tool steel), Hardness ˜210HB, D=180, L=700 mm,
V_{c}=125 m/min
fₙ=0.072 mm/rev
aₚ=2 mm
without cutting fluid

The cut-off criteria for tool life is a flank wear VB of 0.15 mm.

### Flaking Resistance:

The evaluation was made through turning test in austenitic steel. In order to provoke adhesive wear and flaking of the coating the depth of cut aₚ was varied between 4 to 0 and 0 to 4 mm (in one run during radial facing). The inserts were evaluated through SEM analysis.

### Operation: Facing (Turning)

Work piece material: Bar of austenitic stainless steel Sanmac 316L, L=200 mm, D=100 mm, ˜215 HB
Insert type: CNMG 120408-MM
Cooling: yes
Depth of cut aₚ=4 to 0, 0 to 4 mm
Cutting speed V_{c}=140 m/min
Feed rate f_{z}=0.36 mm/rev

### Edge Line Toughness:

Work piece material: Dievar unhardened, P3. 0.Z.AN,
z=1
V_{c}=200 m/min
f_{z}=0.20 mm
aₑ=12 mm
aₚ=3.0
length of cut=12 mm
without cutting fluid

The cut-off criteria are chipping of at least 0.5 mm of the edge line or a measured depth of 0.2 mm at either the flank- or the rake phase. Tool life is presented as the number of cut entrances in order to achieve these criteria.

The results from the cutting tests are seen in Tables 3 to 5.

TABLE 3

| | | | Comb crack | Flank wear |
|---|---|---|---|---|
| | First | Second | resistance | resistance |
| Sample | nanolayer | nanolayer | (No. cuts) | (minutes) |
| 1* | Ti_{0.40}Al_{0.60}N | Ti_{0.50}Al_{0.35}Si_{0.15}N | 36 | 25 |
| 2* | Ti_{0.40}Al_{0.60}N | Ti_{0.50}Al_{0.30}Si_{0.20}N | 33 | 23 |
| 3** | Ti_{0.40}Al_{0.60}N | Ti_{0.35}Al_{0.55}Si_{0.10}N | 32 | 12 |
| 4** | Ti_{0.40}Al_{0.60}N | Ti_{0.30}Al_{0.60}Si_{0.10}N | 30 | 10 |
| 5** | Ti_{0.40}Al_{0.60}N | Ti_{0.80}Si_{0.20}N | 27 | 20 |

*sample within invention
**comparative

Regarding comb crack resistance, all samples 1-4 perform quite well but Sample 1 performs best and there is a decrease in performance in the order Sample 1>Sample 2>Sample 3>Sample 4. Regarding flank wear resistance Sample 1 and Sample 2 perform excellent while Sample 3 and Sample 4 perform much worse.

TABLE 4

| | | | Flaking | Flaking |
|---|---|---|---|---|
| | | | resistance | resistance |
| | | | (flaked area, | (flaked area, |
| | | | mm²) | mm²) |
| | First | Second | RFF 100 | RFF 140 |
| Sample | nanolayer | nanolayer | m/min | m/min |
| 1* | Ti_{0.40}Al_{0.60}N | Ti_{0.50}Al_{0.35}Si_{0.15}N | 0.8 | 0.5 |
| 2* | Ti_{0.40}Al_{0.60}N | Ti_{0.50}Al_{0.30}Si_{0.20}N | 1.7 | 0.6 |
| 3** | Ti_{0.40}Al_{0.60}N | Ti_{0.35}Al_{0.55}Si_{0.10}N | 2.3 | 1.0 |
| 4** | Ti_{0.40}Al_{0.60}N | Ti_{0.30}Al_{0.60}Si_{0.10}N | 2.2 | 0.95 |

*sample within invention
**comparative

Regarding flaking resistance Sample 1 and Sample 2 perform excellent, although a difference is seen for Sample 2 between the flaking test run at 100 m/min and 140 m/min. In this flaking test in stainless steel machining using 100 m/min is the most severe test since more smearing is induced than when using 140 m/min. Sample 3 and Sample 4, comprising nano-multilayers of (Ti,Al)N and (Ti,Al,Si)N with higher Al content in the (Ti,Al,Si)N nanolayers perform much worse in the flaking resistance test at both 100 m/min and 140 m/min.

TABLE 5

| | | | Edge line |
|---|---|---|---|
| | First | Second | toughness |
| Sample | nanolayer | nanolayer | (No. cuts) |
| 1* | Ti_{0.40}Al_{0.60}N | Ti_{0.50}Al_{0.35}Si_{0.15}N | 39 |
| 2* | Ti_{0.40}Al_{0.60}N | Ti_{0.50}Al_{0.30}Si_{0.20}N | 48 |

*sample within invention

Regarding edge line toughness the samples according to the invention perform very well.

1. A coated cutting tool comprising a substrate and a coating, wherein the coating includes a nano-multilayer of alternating layers of a first nanolayer being Ti₁₋ₓAlₓN, 0.55<x≤0.70, and a second nanolayer being Ti_{1-y-z}Al_{y}Si_{z}N, 0.20≤y≤0.50, 0.13≤z≤0.25, 0.46≤y+z≤0.65, wherein a sequence of one first nanolayer and one second nanolayer forms a layer period, and wherein an average layer period thickness in the nano-multilayer is ≤20 nm.

2. The coated cutting tool according to claim 1, wherein for the first nanolayer Ti₁₋ₓAlₓN, 0.56≤x≤0.63.

3. The coated cutting tool according to claim 1, wherein for the second nanolayer Ti_{1-y-z}Al_{y}Si_{z}N, 0.25≤y≤0.45, 0.13≤z≤0.20.

4. The coated cutting tool according to claim 1, wherein for the second nanolayer Ti_{1-y-z}Al_{y}Si_{z}N, 0.46≤y+z≤0.60.

5. The coated cutting tool according to claim 1, wherein for the second nanolayer Ti_{1-y-z}Al_{y}Si_{z}N, 0.33≤y≤0.40, 0.14≤z≤0.17.

6. The coated cutting tool according to claim 1, wherein for the second nanolayer Ti_{1-y-z}Al_{y}Si_{z}N, 0.47≤y+z≤0.55.

7. The coated cutting tool according to claim 1, wherein the average layer period thickness in the nano-multilayer is from 2 to 15 nm.

8. The coated cutting tool according to claim 1, wherein the nano-multilayer has a columnar microstructure.

9. The coated cutting tool according to claim 1, wherein a FWHM value for a cubic peak in X-ray diffraction is from 0.4 to 1 degrees (2theta).

10. The coated cutting tool according to claim 1, wherein a thickness of the nano-multilayer is from about 0.5 to about 15 μm.

11. The coated cutting tool according to claim 1, wherein the coating includes an innermost layer of TiN, (Ti,Al)N or (Cr,Al)N below the nano-multilayer closest to the substrate having a thickness of from about 0.1 to about 3 μm.

12. A coated cutting tool according to claim 11, wherein the innermost layer is Ti₁₋ᵥAlᵥN, 0.35≤v≤0.70.

13. The coated cutting tool according to claim 1, wherein the nano-multilayer is a cathodic arc evaporation deposited layer.

14. The coated cutting tool according to claim 1, wherein the substrate of the coated cutting tool is selected from the group of cemented carbide, cermet, ceramic, cubic boron nitride and high speed steel.

15. The coated cutting tool according to claim 1, wherein the coated cutting tool is a cutting tool insert, a drill, or a solid end-mill, for metal machining.
